(19) United States
(12) Patent Application Publication
(10) Pub. No.: US 2024/0275360 A1
(43) Pub. Date: Aug. 15, 2024

(54) FILTER DEVICE

(71) Applicant: Murata Manufacturing Co., Ltd., Nagaokakyo-shi (JP)

(72) Inventor: Toshiaki TAKATA, Nagaokakyo-shi (JP)

(21) Appl. No.: 18/646,894

(22) Filed: Apr. 26, 2024

Related U.S. Application Data
(63) Continuation of application No. PCT/JP2022/041035, filed on Nov. 2, 2022.

(30) Foreign Application Priority Data
Nov. 9, 2021 (JP) 2021-182609

(51) Int. Cl. H03H 9/56; H03H 9/13

(52) U.S. Cl. CPC H03H 9/568; H03H 9/132; H03H 9/562

(57) ABSTRACT

A filter device includes a piezoelectric substrate, and multiple serial arm resonators and at least one parallel arm resonator on the piezoelectric substrate. First serial arm resonators of the multiple serial arm resonators include a silicon oxide film with a relatively large film thickness. Another of the multiple serial arm resonators is a second serial arm resonator including a silicon oxide film with a relatively small film thickness. Anti-resonant frequencies of the first serial arm resonators are lower than that of the second serial arm resonator. An aspect ratio is determined by a ratio of an intersecting width of electrode fingers of an IDT electrode relative to a number of electrode fingers of the IDT electrode. Aspect ratios of the first serial arm resonators are higher than that of the second serial arm resonator.

### CROSS REFERENCE TO RELATED APPLICATIONS

This application claims the benefit of priority to Japanese Patent Application No. 2021-182609 filed on Nov. 9, 2021 and is a Continuation Application of PCT Application No. PCT/JP2022/041035 filed on Nov. 2, 2022. The entire contents of each application are hereby incorporated herein by reference.

### BACKGROUND OF THE INVENTION

### 1. Field of the Invention

The present invention relates to filter devices each including multiple serial arm resonators and at least one parallel arm resonator including acoustic wave resonators.

### 2. Description of the Related Art

In the related art, ladder filters, each using

multiple acoustic wave resonators, are widely used in bandpass filters. For example, Japanese Unexamined Patent Application Publication No. 2017-526254 discloses a filter device having multiple serial arm resonators and multiple parallel arm resonators. In the filter device, each of the serial arm resonators has a silicon oxide film that is disposed so as to cover an IDT electrode and reflectors. The film thickness of the silicon oxide film of a serial arm resonator having a low anti-resonant frequency is larger than that of a serial arm resonator having a high anti-resonant frequency.

### SUMMARY OF THE INVENTION

The filter device described in Japanese Unexamined Patent Application Publication No. 2017-526254 enables changes to the frequency-temperature characteristics to be suppressed, and also enables the passband to be widened. However, the film thickness of the silicon oxide film of a serial arm resonator having a low anti-resonant frequency is large. Thus, there arises a problem of larger loss on the higher range side in the passband.

Example embodiments of the present invention provide filter devices that each achieve a reduction of loss on a higher range side in a passband.

A filter device according to an example embodiment of the present invention includes a plurality of serial arm resonators each defined by an acoustic wave resonator, and at least one parallel arm resonator defined by an acoustic wave resonator. Each of the acoustic wave resonators includes a piezoelectric substrate, an IDT electrode and a pair of reflectors on the piezoelectric substrate, and a silicon oxide film covering the IDT electrode and the pair of reflectors. An anti-resonant frequency of a first serial arm resonator is lower than an anti-resonant frequency of a second serial arm resonator, where, among the plurality of serial arm resonators, a serial arm resonator whose silicon oxide film has a relatively large film thickness is regarded as the first serial arm resonator, and where a serial arm resonator whose silicon oxide film has a relatively small film thickness is regarded as the second serial arm resonator. An aspect ratio of the first serial arm resonator is larger than an aspect ratio of the second serial arm resonator, where the aspect ratio refers to a ratio of an intersecting width of electrode fingers of an IDT electrode to a number of electrode fingers of the IDT electrode.

Example embodiments of the present invention provide filter devices having a small loss in the higher range side in the passband.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a filter device according to a first example embodiment of the present invention.

FIG. 2 is a circuit diagram of a multiplexer including a filter device according to the first example embodiment of the present invention.

FIG. 3 is an elevational cross-sectional view of the structure of an acoustic wave resonator included in a filter device according to the first example embodiment of the present invention.

FIG. 4 is a schematic plan view of the electrode structure of the acoustic wave resonator illustrated in FIG. 3.

FIG. 5 is a diagram illustrating return loss characteristics in an example case where, in a surface acoustic wave resonator having an anti-resonant frequency of about 858 MHz, the film thickness of the silicon oxide film is about 1665 nm or about 970 nm.

FIG. 6 is a diagram illustrating impedance characteristics in an example case where, in a surface acoustic wave resonator having an anti-resonant frequency of about 858 MHz, the film thickness of the silicon oxide film is about 1665 nm or about 970 nm.

FIG. 7 is a diagram illustrating return loss characteristics in the case where, in an example of a surface acoustic wave resonator having an anti-resonant frequency of about 878 MHz, the film thickness of the silicon oxide film is about 970 nm or about 1665 nm, for example.

FIG. 8 is a diagram illustrating impedance characteristics in an example case where, in a surface acoustic wave resonator having an anti-resonant frequency of about 878 MHz, the film thickness of the silicon oxide film is about 970 nm or about 1665 nm, for example.

FIG. 9 is a diagram illustrating filter characteristics of filter devices according to an example embodiment example and a comparison example.

FIG. 10 is a diagram illustrating return loss characteristics of a serial arm resonator S3 alone, which is included in filter devices according to an example embodiment example and the comparison example.

FIG. 11 is a diagram illustrating return loss characteristics of a serial arm resonator S1 alone, which is included in filter devices according to an example embodiment example and the comparison example.

FIG. 12 is a diagram illustrating return loss characteristics of a serial arm resonator S3 alone, in the case where the number of electrode fingers of each reflector is 13 or 7, for example.

FIG. 13 is a diagram illustrating return loss characteristics of a serial arm resonator S1 alone, in the case where the number of electrode fingers of each reflector is 13 or 7, for example.

FIG. 14 is an elevational cross-sectional view of another example of a structure of an acoustic wave resonator according to an example embodiment of the present invention.

### DETAILED DESCRIPTION OF THE EXAMPLE EMBODIMENTS

Referring the to drawings, specific example embodiments of the present invention will be described below.

It is to be noted that the example embodiments described in the specification are exemplary, and that partial replacement or combination of configurations may be made among different example embodiments.

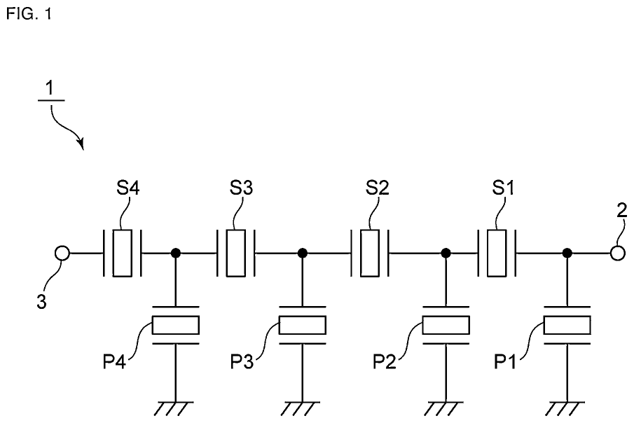

FIG. 1 is a circuit diagram of a filter device according to a first example embodiment of the present invention. A filter device 1 is a transmit filter for Band 26, for example. The transmit band of Band 26 is about 814 MHz to about 849 MHz, and the receive band is about 859 MHz to about 894 MHz, for example.

The filter device 1 includes multiple serial arm resonators S1 to S4 and multiple parallel arm resonators P1 to P4, which are defined by surface acoustic wave resonators. In the filter device 1, the serial arm resonator S1 is connected to a transmit terminal 2. The serial arm resonator S4 is connected to an antenna terminal 3. The parallel arm resonator P1 is connected between the ground potential and the connecting point between the serial arm resonator S1 and the transmit terminal 2. The parallel arm resonator P2 is connected between the ground potential and the connecting point between the serial arm resonator S1 and the serial arm resonator S2. The parallel arm resonator P3 is connected between the ground potential and the connecting point between the serial arm resonator S2 and the serial arm resonator S3. The parallel arm resonator P4 is connected between the ground potential and the connecting point between the serial arm resonator S3 and the serial arm resonator S4.

Each of the serial arm resonators S1 to S4 and the parallel arm resonators P1 to P4 is defined by a surface acoustic wave resonator. Therefore, the filter device 1 is a ladder filter including multiple surface acoustic wave resonators.

The number of parallel arm resonators is not limited to a plurality, and may be one.

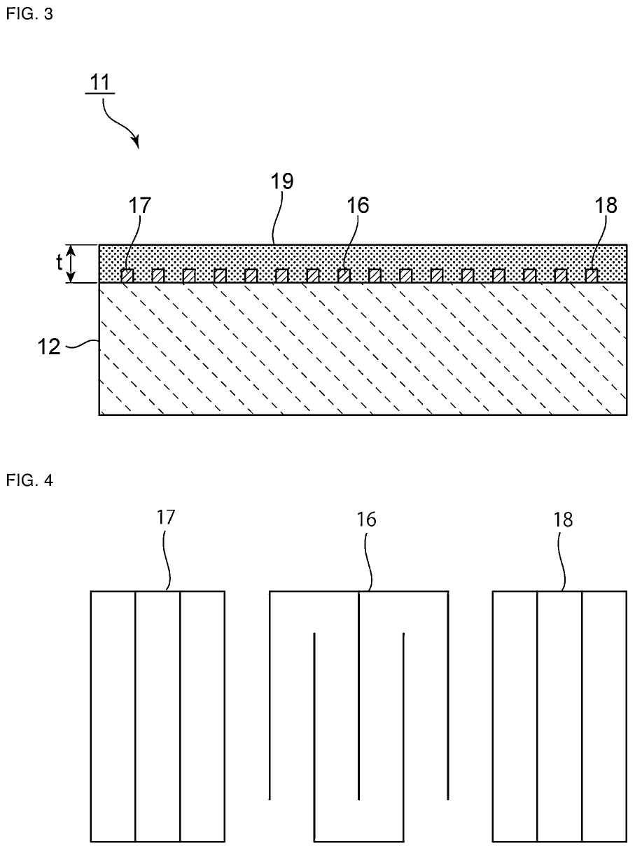

FIG. 3 illustrates an exemplary structure of a surface acoustic wave resonator used as the serial arm resonators S1 to S4 and the parallel arm resonators P1 to P4 in the filter device 1. FIG. 4 is a schematic plan view of the electrode structure provided on a piezoelectric substrate. As illustrated in FIG. 3, an acoustic wave resonator 11 includes a piezoelectric substrate 12. The piezoelectric substrate 12 is formed, for example, of a piezoelectric single-crystal, such as LiNbO₃ or LiTaO₃. An IDT electrode 16 and reflectors 17 and 18 are disposed on the piezoelectric substrate 12. The acoustic wave resonator 11, which includes the piezoelectric substrate 12 including Y-cut LiNbO₃, is a surface acoustic wave resonator using Rayleigh waves.

A silicon oxide film 19 is disposed so as to cover the IDT electrode 16 and the pair of reflectors 17 and 18 of the surface acoustic wave resonator, for improvement of the frequency-temperature characteristics. The film thickness t of the silicon oxide film 19 is a dimension from the top surface of the piezoelectric substrate 12 to the top surface of the silicon oxide film 19.

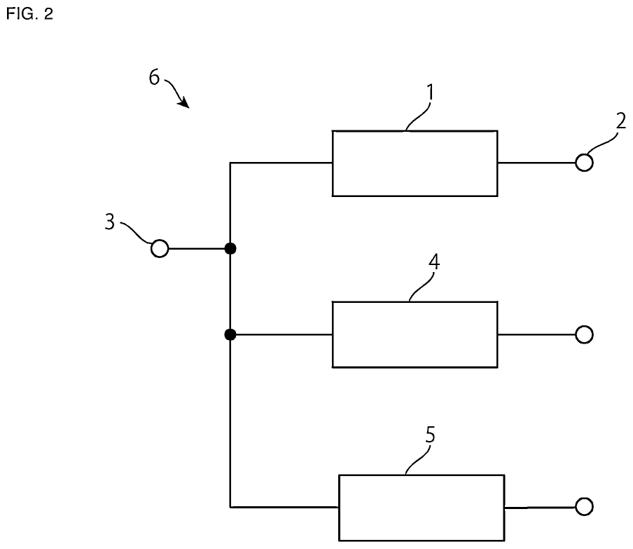

The filter device 1 is included in a multiplexer illustrated in FIG. 2. In the multiplexer in FIG. 2, the filter device 1 is connected, at its end, to ends of different bandpass filters 4 and 5 at a common connecting point. That is, their ends are connected to one another at the common connecting point connected to the antenna terminal 3. A filter device according to an example embodiment of the present invention may be applied to a multiplexer, and also to a duplexer including the filter device 1 and another bandpass filter.

In the filter device 1, the serial arm resonators S2 to S4 among the serial arm resonators S1 to S4 correspond to first serial arm resonators, and the serial arm resonator S1 corresponds to a second serial arm resonator. The anti-resonant frequencies of the serial arm resonators S2 to S4 are lower than that of the serial arm resonator S1. The film thicknesses of the silicon oxide films of the serial arm resonators S2 to S4 are larger than that of the serial arm resonator S1. The aspect ratios of the serial arm resonators S2 to S4 are larger than that of the serial arm resonator S1. The aspect ratio refers to a ration of an intersecting width of electrode fingers of an IDT electrode to a number of electrode fingers of the IDT electrode. The intersecting width of electrode fingers is a dimension, in the direction in which electrode fingers extend, of a portion in which adjacent electrode fingers intersect each other. In the filter device 1, the film thicknesses of the silicon oxide films of the serial arm resonators S2 to S4 are larger, causing the frequency-temperature characteristics to be improved. Further, return loss on the higher range side in the passband may be decreased. Therefore, the loss on the higher range side in the passband may be decreased.

This will be clarified by describing an example embodiment example and a comparison example.

For the serial arm resonators S1 to S4 and the parallel arm resonators P1 to P4, a structure in which an IDT electrode and a pair of reflectors are provided on a piezoelectric substrate that is preferably a Y-cut LiNbO₃ substrate, is preferably used.

The parameters of the serial arm resonators S1 to S4 in a filter device according to an example embodiment example are illustrated in Table 1 below.

TABLE 1

| | | S4 | | S3 | | S2 | | S1 | |
|---|---|---|---|---|---|---|---|---|---|
| | SiO₂ film | 1665 | nm | 1665 | nm | 1665 | nm | 970 | nm |
| | thickness | | | | | | | | |
| | anti- | 863 | MHz | 858 | MHz | 861 | MHz | 878 | MHz |
| | resonant | | | | | | | | |
| | frequency | | | | | | | | |
| the | the number | 157 | | 187 | | 172 | | 195 | |
| present | of electrode | | | | | | | | |
| invention | fingers of | | | | | | | | |
| | IDT | | | | | | | | |
| | electrode | | | | | | | | |
| | the number | 13 | | 13 | | 13 | | 7 | |
| | of electrode | | | | | | | | |
| | fingers of | | | | | | | | |
| | reflector | | | | | | | | |
| | intersecting | 19.0 | λ | 19.5 | λ | 19.8 | λ | 10.1 | λ |
| | width | | | | | | | | |
| | aspect ratio | 0.121 | | 0.104 | | 0.115 | | 0.051 | |
| comparison | the number | 182 | | 261 | | 229 | | 113 | |
| example | of electrode | | | | | | | | |
| | fingers of | | | | | | | | |
| | IDT | | | | | | | | |
| | electrode | | | | | | | | |
| | the number | 13 | | 13 | | 13 | | 7 | |
| | of electrode | | | | | | | | |
| | fingers of | | | | | | | | |
| | reflector | | | | | | | | |
| | intersecting | 16.4 | λ | 14.0 | λ | 14.9 | λ | 17.4 | λ |
| | width | | | | | | | | |

| | | | | |
|---|---|---|---|---|
| aspect ratio | 0.090 | 0.054 | 0.065 | 0.154 |

The parameters of the parallel arm resonators P1 to P4 are illustrated in Table 2 below.

TABLE 2

| | | P4 | | P3 | | P2 | | P1 | |
|---|---|---|---|---|---|---|---|---|---|
| | SiO₂ film | 970 | nm | 970 | nm | 970 | nm | 970 | nm |
| | thickness | | | | | | | | |
| | anti- | 831 | MHz | 833 | MHz | 835 | MHz | 832 | MHz |
| | resonant | | | | | | | | |
| | frequency | | | | | | | | |
| the | the number | 270 | | 150 | | 260 | | 70 | |
| present | of electrode | | | | | | | | |
| invention | fingers of | | | | | | | | |
| comparison | IDT | | | | | | | | |
| example | electrode | | | | | | | | |
| | the number | 11 | | 11 | | 11 | | 11 | |
| | of electrode | | | | | | | | |
| | fingers of | | | | | | | | |
| | reflector | | | | | | | | |
| | intersecting | 25 | λ | 18.4 | λ | 16 | λ | 15 | λ |
| | width | | | | | | | | |

| | | | | |
|---|---|---|---|---|
| aspect ratio | 0.093 | 0.123 | 0.062 | 0.214 |

In Table 1, the intersecting width is expressed as a multiple of wavelength A. Alternatively, the intersecting width may be expressed as a value obtained through normalization of the dimension of the intersecting width with wavelength A. The wavelength A is a wavelength determined by the electrode finger pitch of an IDT electrode. As described above, the aspect ratio refers to a ration between the intersecting width of the electrode fingers of an IDT electrode and the number of electrode fingers of the IDT electrode. A smaller aspect ratio indicates a larger number of electrode fingers of the IDT electrode and/or a narrow intersecting width of the electrode fingers of the IDT electrode.

As illustrated in Table 1, the film thicknesses of the silicon oxide films of the serial arm resonators S2 to S4 are larger than that of the serial arm resonator S1.

As illustrated in Table 2, the film thicknesses of the silicon oxide films of the parallel arm resonators P1 to P4 are the same as that of the serial arm resonator S1, which is about 970 nm, for example.

In the comparison example, the aspect ratio of the serial arm resonator S1 is 0.154; the aspect ratios of the serial arm resonators S2 to S4 are 0.065, 0.054, and 0.090. That is, the aspect ratio of the serial arm resonator S1 is larger than the aspect ratios of the serial arm resonators S2 to S4.

The comparison example is different from the example embodiment example only in the aspect ratio. That is, for each IDT electrode, the number of electrode fingers and the intersecting width of the electrode fingers in the comparison example are different from those in the example embodiment example. However, the capacitance value proportional to (the number of electrode fingers of an IDT electrode x the intersecting width of the electrode fingers of the IDT electrode) is the same. In the comparison example, the anti-resonant frequencies and the film thicknesses of the silicon oxide films of the serial arm resonators S1 to S4 are substantially the same as those in the example embodiment example.

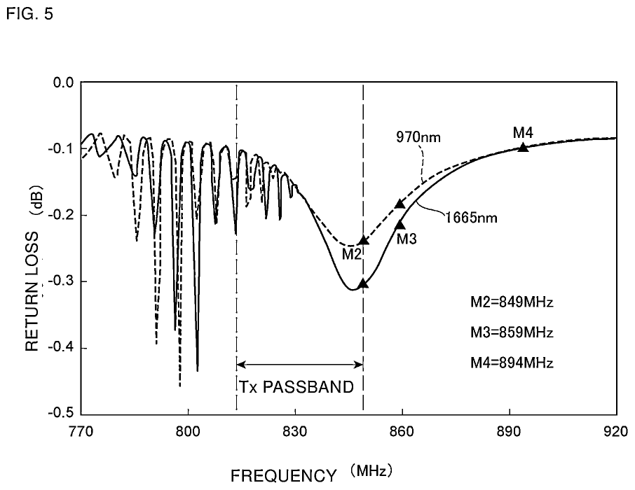

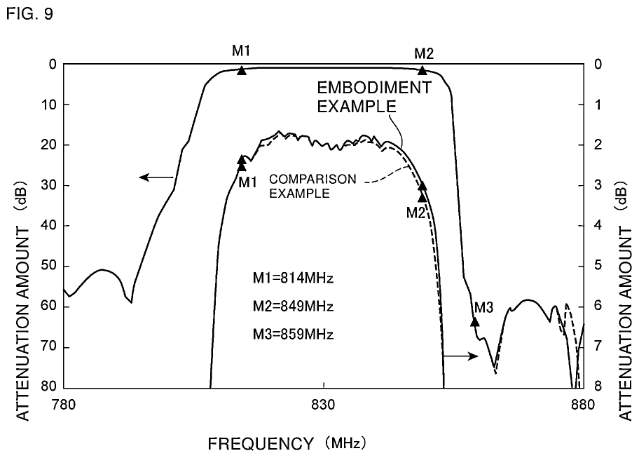

FIG. 9 illustrates filter characteristics of filter devices of the example embodiment example and the comparison example. In the characteristic diagrams, such as FIG. 9 and FIGS. 5 and 6 described below, M1 indicates the frequency position of about 814 MHz, which is the lower end of the communication band of Band 26; M2 indicates the frequency position of about 849 MHz, which is the upper end. M3 indicates the frequency position of about 859 MHZ, which is the lower end of the receive band of Band 26; M4 indicates about 894 MHz, which is the upper end of the receive band of Band 26.

As is clear from FIG. 9, in a range at and near 849 MHz which is an end portion on the higher range side in the passband, the example embodiment example has a smaller loss than the comparison example. That is, the loss on the higher range side in the passband may be decreased.

This is due to the following reasons.

FIG. 5 illustrates return loss characteristics in the case where, in a surface acoustic wave resonator having an anti-resonant frequency of about 858 MHZ, the film thickness of the silicon oxide film is about 1665 nm or about 970 nm, for example.

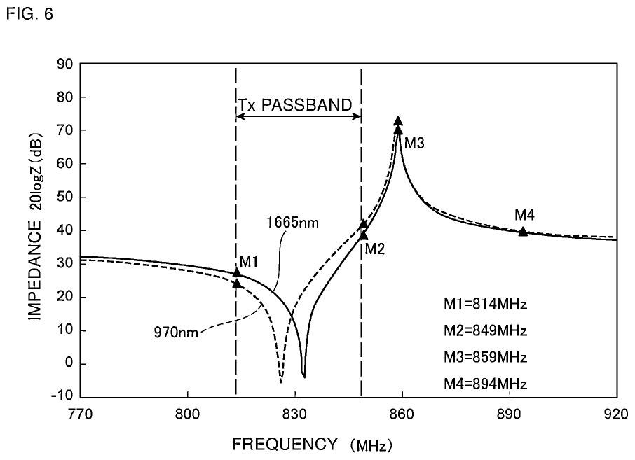

FIG. 6 illustrates impedance characteristics in the case where, in a surface acoustic wave resonator having an anti-resonant frequency of about 858 MHz, the film thickness of the silicon oxide film is about 1665 nm or about 970 nm, for example.

As is clear from FIGS. 5 and 6, in the surface acoustic wave resonator having an anti-resonant frequency of 858 MHz, when the film thickness of the silicon oxide film is changed from about 1665 nm to about 970 nm, the absolute value of return loss is substantially decreased at about 849 MHz in the end portion on the higher range side in the passband, for example, indicating improvement.

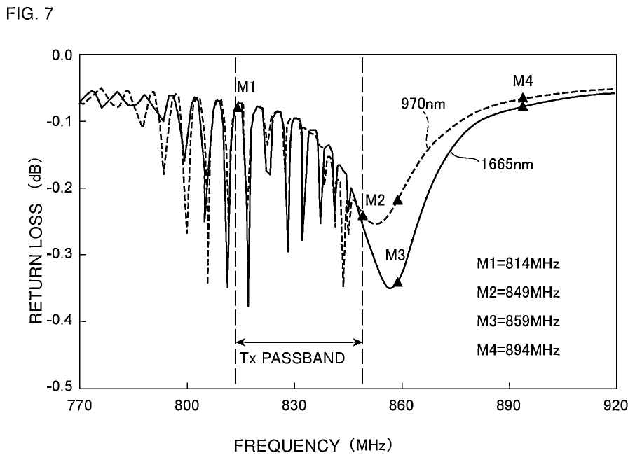

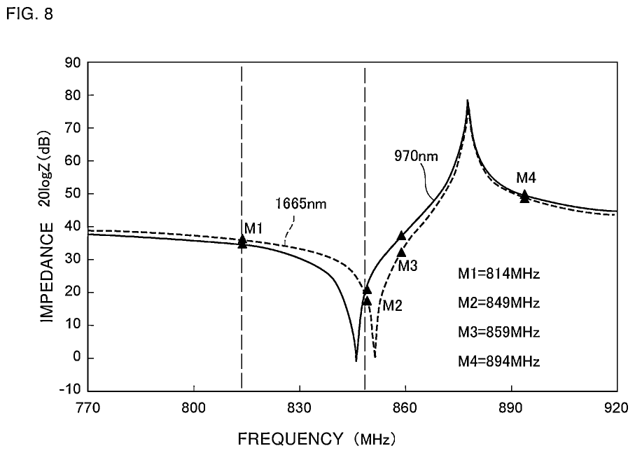

In contrast, FIG. 7 illustrates return loss characteristics in the case where, in a surface acoustic wave resonator having an anti-resonant frequency of about 878 MHZ, the film thickness of the silicon oxide film is about 970 nm or about 1665 nm, for example. FIG. 8 illustrates impedance characteristics in the case where, in a surface acoustic wave resonator having an anti-resonant frequency of about 878 MHZ, the film thickness of the silicon oxide film is about 970 nm or about 1665 nm, for example.

As is clear from FIGS. 7 and 8, in a surface acoustic wave resonator having a high anti-resonant frequency of about 878 MHz, for example, most of the wave number range from the resonant frequency to the anti-resonant frequency is not included in the transmit band of Band 26. Therefore, in the case where the anti-resonant frequency is high, even if the film thickness of the silicon oxide film is about 1665 nm, for example, which indicates being thick, degradation of return loss on the higher range side in the transmit band is substantially small.

Therefore, it is discovered and confirmed that, if the film thickness of the silicon oxide film in a serial arm resonator having an anti-resonant frequency on the low side is large to improve of the temperature characteristics, loss on the higher range side in the passband increases, causing degradation.

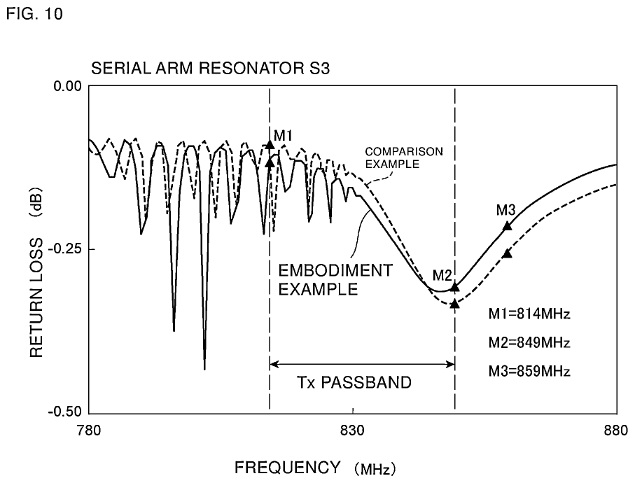

In contrast, FIG. 10 illustrates return loss

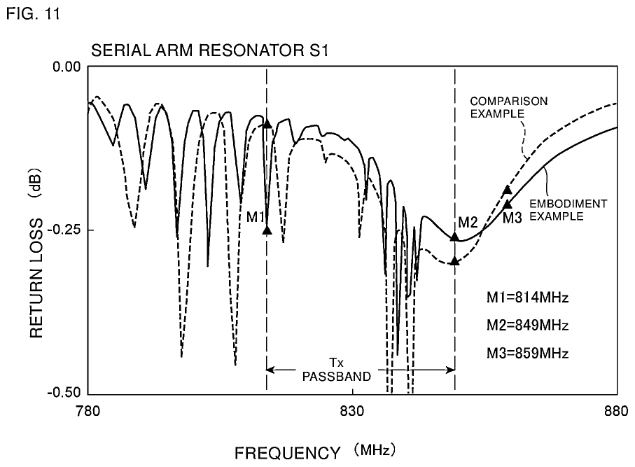

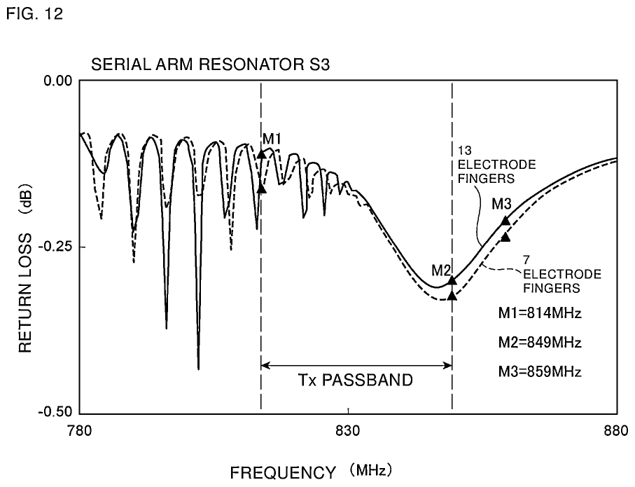

characteristics of the serial arm resonator S3 alone, according to the example embodiment example and the comparison example. FIG. 11 illustrates return loss characteristics of the serial arm resonator S1 alone, according to the example embodiment example and the comparison example.

As illustrated in FIG. 10, in the serial arm resonator S3 which is a first serial arm resonator, the aspect ratio, which is about 0.104, is higher than about 0.054 in the case of the comparison example, for example. Therefore, return loss on the higher range side in the passband is improved. As is clear from FIG. 11, in the serial arm resonator S1 which is a second serial arm resonator, the aspect ratio of the example embodiment example, which is about 0.051, is lower than the aspect ratio of the comparison example, which is about 0.154, for example. Therefore, also in the return loss characteristics of the serial arm resonator S1 alone, return loss on the higher range side in the passband is improved.

Therefore, as illustrated in FIG. 9, the filter device 1 is intended to have a lower loss on the higher range side in the passband.

A larger aspect ratio causes degradation of return loss at and near the resonant frequency, but causes improvement of return loss characteristics at and near the anti-resonant frequency. The serial arm resonator S3 has a low anti-resonant frequency which is close to the higher range side in the passband. Therefore, in the example embodiment example, the aspect ratio is increased to improve return loss at and near the anti-resonant frequency. Consequently, the return loss on the higher range side in the passband is improved.

In contrast, the serial arm resonator S1 has a high anti-resonant frequency and a resonant frequency which is close to the higher range side in the passband. Therefore, in the example embodiment example, the aspect ratio is decreased to improve return loss characteristics at and near the resonant frequency. Consequently, the serial arm resonator S1 also achieves improvement of return loss at about 849 MHz on the higher range side in the passband, for example.

That is, in an example embodiment of the present invention, the aspect ratios of the serial arm resonators S2 to S4, which have low anti-resonant frequencies, are increased, and the aspect ratio of the serial arm resonator S1, which has a high anti-resonant frequency, is decreased. Thus, the return loss, on the higher range side in the passband, of each serial arm resonator alone is improved. Accordingly, the filter device 1 is intended to have a low loss on the higher range side in the passband.

The anti-resonant frequencies of surface acoustic wave resonators may be compared with each other by using their electrode finger pitches and duty ratios. For example, when surface acoustic wave resonators have electrode fingers having the same thickness, the anti-resonant frequency of a surface acoustic wave resonator, which has a larger reciprocal of the product of the electrode finger pitch and the duty ratio, is higher than that of the other surface acoustic wave resonator.

Further, in addition, if the surface acoustic wave resonators have electrode fingers having different anti-resonant frequency of a surface thicknesses, the acoustic wave resonator, whose reciprocal of the product of the electrode finger pitch, the duty ratio, and the thickness of the electrode fingers, that is, the value of 1/(the electrode finger pitch×the duty ratio×the thickness of the electrode fingers), is larger, is higher than that of the other surface acoustic wave resonator.

Preferably, the number of electrode fingers of the IDT electrode of the second serial arm resonator is larger than those of the first serial arm resonators. This may cause the first serial arm resonators to have effective improvement of return loss at and near their resonant frequencies. Therefore, the loss of the filter device may be decreased.

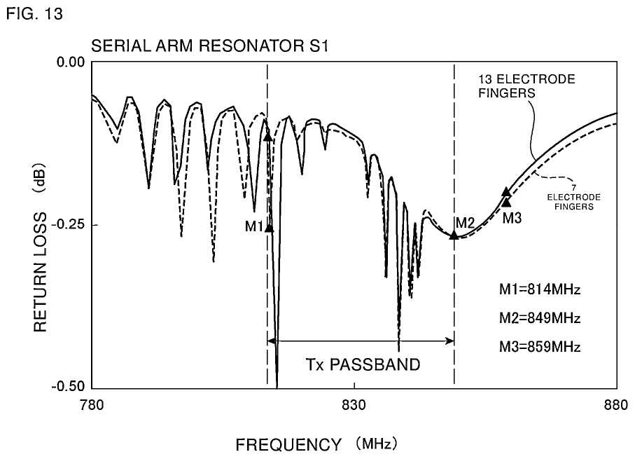

In addition, in an example embodiment of the present invention, the number of electrode fingers of each individual reflector of each first serial arm resonator is preferably greater than that of the second serial arm resonator. A larger number of electrode fingers of each individual reflector enables the return loss characteristics to be improved. Therefore, the filter device achieves a smaller insertion loss. This will be described by referring to FIGS. 12 and 13.

FIG. 12 illustrates return loss characteristics in the case where, in the serial arm resonator S3 which is a first serial arm resonator, the number of electrode fingers of each individual reflector is 13 or 7, for example. FIG. 13 illustrates return loss characteristics in the case where, in the serial arm resonator S1, the number of electrode fingers of each individual reflector is 13 or 7, for example.

As is clear from FIG. 12, the serial arm resonator S3 achieves improvement of return loss in the case of a larger number of electrode fingers of each individual reflector.

In the serial arm resonator S1 whose anti-resonant frequency is far from the transmit band, the resonant frequency is closer to the transmit band. Therefore, the magnitude of the number of electrode fingers of each individual reflector has little or no effect the return loss at about 849 MHz, for example. The smaller the number of electrode fingers of each individual reflector is, the smaller the area of the IDT electrode is. Thus, the first serial arm resonators are intended to have a reduction in size. In addition, the loss, on the higher range side in the passband, of the filter characteristics may be decreased.

Preferably, the anti-resonant frequency of the serial arm resonator S1, which is a second serial arm resonator, is higher than those of the other serial arm resonators S2 to S4, which define the passband, and the resonant frequency of the serial arm resonator S1 is on the higher range side than the passband. Serial arm resonators defining a passband indicate that their resonant frequencies are positioned in the passband. A serial arm resonator, whose resonant frequency is positioned outside a passband, does not define the passband.

A smaller aspect ratio may degrade return loss at and near the anti-resonant frequency. However, a resonant frequency, which is made to be positioned outside the passband and near an end portion on the higher range side in the passband, enables a range of degradation of return loss to be shifted to the higher range side than the passband. Therefore, the loss may be further decreased.

Preferably, the aspect ratio of the serial arm resonator S1, which is a second serial arm resonator, is the smallest among those of all the serial arm resonators in the filter device. This achieves further improvement of return loss at and near the resonant frequency and further decrease of the loss of the filter device.

The aspect ratios of the serial arm resonators S2 to S4 are higher than that of the serial arm resonator S1. In addition, the intersecting width is preferably greater than or equal to about 17 Å, for example. A larger intersecting width causes further improvement of return loss at and near the anti-resonant frequency. However, if the intersecting width exceeds about 17 Å, for example, the amount of improvement decreases gradually. In contrast, in the serial arm resonator S1 which is a second serial arm resonator, degradation of return loss at and near the anti-resonant frequency does not occur in the passband. Therefore, even if the intersecting width is less than about 17 Å, little or no influence occurs, for example.

Therefore, the aspect ratio of the serial arm resonator S1 is preferably decreased so that the intersecting widths of the serial arm resonators S2 to S4 are greater than or equal to about 17 Å, and that the intersecting width of the serial arm resonator S1 is less than about 17 Å, for example.

In an example embodiment of the present invention, the film thickness of the silicon oxide film of the second serial arm resonator is desirably equal to those of the parallel arm resonators. In this case, the silicon oxide films may be formed through the same process. Therefore, the cost of manufacture may be reduced. In addition, small film thicknesses of the silicon oxide films of the parallel arm resonators cause the interval between the resonant frequency and the anti-resonant frequency to be widened. Therefore, a wider-band filter device may be provided.

As illustrated in FIG. 2, a filter device according to an example embodiment of the present invention is suitably used in a multiplexer. Alternatively, the filter device may be used as a single filter device or may be used in a duplexer. In the case of use in a duplexer, changes in the temperature characteristics in the passband of the filter device itself may be reduced or prevented. In addition, since changes in characteristics in the passband of the filter device may be decreased or prevented, changes in characteristics of the other bandpass filters, which are connected in common, may be reduced or prevented.

Preferably, the first serial arm resonators are desirably disposed on the antenna terminal side, and the second serial arm resonator is desirably disposed on the signal terminal side which is the opposite side. That is, for example, the serial arm resonator S4, which has a low anti-resonant frequency and in which the film thickness of the silicon oxide film is large, is desirably disposed on the antenna terminal side. In addition, a serial arm resonator like the serial arm resonator S1, which has a high anti-resonant frequency and in which the film thickness of the silicon oxide film is small, is desirably disposed on the signal terminal side. A large film thickness of the silicon oxide film of a serial arm resonator on the antenna terminal side achieves reduction or prevention of changes, due to temperature, of characteristics of impedance as seen from the antenna terminal. Therefore, changes in characteristics of the other bandpass filters, which are connected in common, may be reduced or prevented. In addition, a small film thickness of a silicon oxide film on the signal terminal side enables the interval between the resonant frequency and the anti-resonant frequency to be widened. Therefore, the inductive region is widened. Consequently, the value of an inductance device connected between the signal terminal and a connected amplifier may be decreased. Therefore, degradation of loss due to the inductance device may be also reduced or prevented.

In the case where the signal terminal is a receive terminal, the inductance value of an inductance device connected between the receive terminal and a low-noise amplifier (LNA) may be decreased. Also in this case, degradation of loss due to the inductance device may be reduced or prevented.

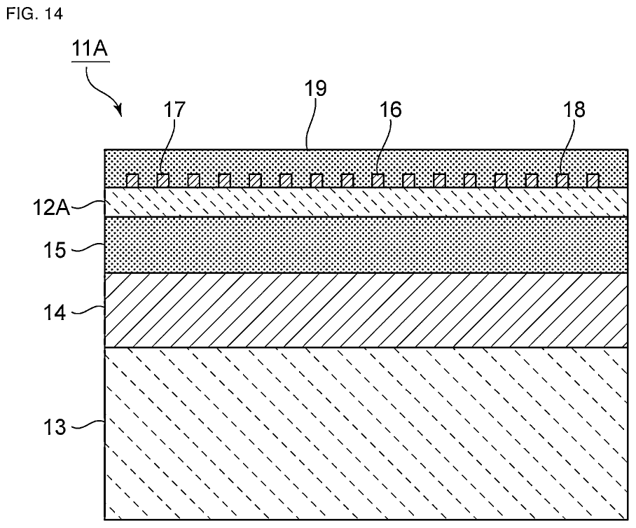

FIG. 14 is an elevational cross-sectional view of another example of the structure of an acoustic wave resonator included in a filter device according to an example embodiment of the present invention. An acoustic wave resonator 11A includes a support substrate 13. The support substrate 13 is made of Si. Alternatively, the support substrate 13 may be formed by using an appropriate insulator or semiconductor. On the support substrate 13, a high-acoustic-velocity member 14, a low-acoustic-velocity film 15, and a piezoelectric layer 12A are laminated in this order. A piezoelectric substrate having such a layered structure may be used. The piezoelectric layer 12A is preferably made of piezoelectric single-crystal. In the present example embodiment, LiTaO₃ is preferably used. Alternatively, other piezoelectric single-crystal such as LiNbO₃ may be used. The IDT electrode 16 and the reflectors 17 and 18 are disposed on the piezoelectric layer 12A.

The high-acoustic-velocity member 14 is made of a high-acoustic-velocity material. The high-acoustic-velocity material refers to a material in which the acoustic velocity of propagating bulk waves is higher than that of acoustic waves propagating through the piezoelectric layer 12A. As such a high-acoustic-velocity material, various materials, such as aluminum oxide, silicon carbide, silicon nitride, silicon oxynitride, silicon, sapphire, lithium tantalate, lithium niobate, crystal, alumina, zirconia, cordierite, mullite, steatite, forsterite, magnesia, a DLC (diamond-like carbon) film, diamond, a medium, the main component of which is among the materials, and a medium, the main component of which is a mixture of materials described above, may be used. In the present example embodiment, the high-acoustic-velocity member 14 is made of silicon nitride.

The low-acoustic-velocity film 15 is made of a low-acoustic-velocity material. The low-acoustic-velocity material refers to a material in which the acoustic velocity of propagating bulk waves is lower than that of bulk waves propagating through the piezoelectric layer 12A. As such a low-acoustic-velocity material, various materials, such as silicon oxide, glass, silicon oxynitride, tantalum oxide, a compound, which is obtained by adding fluorine, carbon, boron, hydrogen, or a silanol group to silicon oxide, and a medium, the main component of which is among the materials, may be used. In the present example embodiment, the low-acoustic-velocity film 15 is made of silicon oxide.

In the acoustic wave resonator 11A illustrated in FIG. 14, the high-acoustic-velocity member 14 and the low-acoustic-velocity film 15 are laminated. Alternatively, a structure in which the support substrate 13 and the high-acoustic-velocity member 14 are integrated by using a high-acoustic-velocity material may be used. That is, the piezoelectric substrate may have a structure in which the low-acoustic-velocity film 15 is laminated between the support substrate including the high-acoustic-velocity material and the piezoelectric layer 12A. In addition, the low-acoustic-velocity film 15 may be omitted. That is, the piezoelectric layer 12A may be laminated on the high-acoustic-velocity member 14 directly, or may be directly laminated on the support substrate including the high-acoustic-velocity material.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a plurality of serial arm resonators each including an acoustic wave resonator; and
at least one parallel arm resonator defined by an acoustic wave resonator; wherein
each of the acoustic wave resonators includes a piezoelectric substrate, an IDT electrode and a pair of reflectors on the piezoelectric substrate, and a silicon oxide film covering the IDT electrode and the pair of reflectors;
an anti-resonant frequency of a first serial arm resonator is lower than an anti-resonant frequency of a second serial arm resonator, where, among the plurality of serial arm resonators, a serial arm resonator whose silicon oxide film has a relatively large film thickness is regarded as the first serial arm resonator, and where a serial arm resonator whose silicon oxide film has a relatively small film thickness is regarded as the second serial arm resonator; and
an aspect ratio of the first serial arm resonator is larger than an aspect ratio of the second serial arm resonator, where the aspect ratio refers to a ratio of an intersecting width of electrode fingers of an IDT electrode to a number of electrode fingers of the IDT electrode.

2. The filter device according to claim 1, wherein the number of electrode fingers of the IDT electrode of the second serial arm resonator is greater than the number of electrode fingers of the IDT electrode of the first serial arm resonator.

3. The filter device according to claim 1, wherein the number of electrode fingers of each of the reflectors of the first serial arm resonator is greater than the number of electrode fingers of each of the reflectors of the second serial arm resonator.

4. The filter device according to claim 1, wherein the second serial arm resonator has a highest anti-resonant frequency among the other serial arm resonators defining a passband, and has a resonant frequency on a higher range side than the passband.

5. The filter device according to claim 1, wherein the aspect ratio of the second serial arm resonator is smallest among the aspect ratios of the plurality of serial arm resonators.

6. The filter device according to claim 1, wherein the film thickness of the silicon oxide film of the second serial arm resonator is equal to the film thickness of the silicon oxide film of the parallel arm resonator.

7. The filter device according to claim 1, wherein a transmit band is about 814 MHz to about 849 MHz, and a receive band is about 859 MHz to about 894 MHz.

8. The filter device according to claim 1, wherein the filter device is a ladder filter.

9. The filter device according to claim 1, wherein the at least one parallel arm resonator includes only one parallel arm resonator.

10. The filter device according to claim 1, wherein the at least one parallel arm resonator includes a plurality of parallel arm resonators.

11. The filter device according to claim 1, wherein the film thickness of the silicon oxide film of the second serial arm resonator and the film thickness of the silicon oxide film of the parallel arm resonator are about 970 nm.

12. A duplexer comprising:
the filter device according to claim 1; and
another bandpass filter.

13. A multiplexer, comprising:
a plurality of bandpass filters connected in common at first ends thereof; wherein
at least one of the plurality of bandpass filters is the filter device according to claim 1.

14. The multiplexer according to claim 13, wherein
the first end of the multiplexer is connected to an antenna terminal; and
the first serial arm resonator is a serial arm resonator closest to the antenna terminal in the filter device.

15. The multiplexer according to claim 13, wherein, in the filter device, the second serial arm resonator is a serial arm resonator closest to a second end opposite to a side of the first end.

16. The multiplexer according to claim 13, wherein the number of electrode fingers of the IDT electrode of the second serial arm resonator is greater than the number of electrode fingers of the IDT electrode of the first serial arm resonator.

17. The multiplexer according to claim 13, wherein the number of electrode fingers of each of the reflectors of the first serial arm resonator is greater than the number of electrode fingers of each of the reflectors of the second serial arm resonator.

18. The multiplexer according to claim 13, wherein the second serial arm resonator has a highest anti-resonant frequency among the other serial arm resonators defining a passband, and has a resonant frequency on a higher range side than the passband.

19. The multiplexer according to claim 13, wherein the aspect ratio of the second serial arm resonator is smallest among the aspect ratios of the plurality of serial arm resonators.

20. The multiplexer according to claim 13, wherein the film thickness of the silicon oxide film of the second serial arm resonator is equal to the film thickness of the silicon oxide film of the parallel arm resonator.
